(19) United States
(12) Patent Application Publication
(10) Pub. No.: US 2023/0317644 A1
(43) Pub. Date: Oct. 5, 2023

(54) ROUTABLE MULTILEVEL PACKAGE WITH MULTIPLE INTEGRATED ANTENNAS

(71) Applicant: Texas Instruments Incorporated, Dallas, TX (US)

(72) Inventors: Juan Alejandro Herbsommer, Allen, TX (US); Yiqi Tang, Allen, TX (US); Rajen Manicon Murugan, Dallas, TX (US)

(21) Appl. No.: 17/710,931

(22) Filed: Mar. 31, 2022

(51) Int. Cl. H01L 23/66; H01L 23/00; H01L 23/495; H01Q 1/38; H01Q 1/22; H01Q 3/36; H01Q 21/06; H01Q 3/44; H01Q 5/371; H01Q 1/42; H01Q 15/00

(52) U.S. Cl. CPC H01L 23/66; H01L 24/16; H01L 24/13; H01L 23/49534; H01L 23/49548; H01L 23/49541; H01Q 1/38; H01Q 1/2283; H01Q 3/36; H01Q 21/065; H01Q 3/44; H01Q 5/371; H01Q 1/422; H01Q 15/0026; H01L 2223/6616; H01L 2223/6677; H01L 24/32; H01L 24/73; H01L 2224/73204; H01L 2224/32245; H01L 2224/16245; H01L 2224/13147; H01L 2224/13611; H01L 2224/13639; H01L 2224/13647; H01L 2924/182; H01Q 21/10

(57) ABSTRACT

Described examples include an apparatus having a first antenna and a second antenna formed in a first layer on a first surface of a multilayer package substrate, the multilayer package substrate having layers including patterned conductive portions and dielectric portions, the multilayer package substrate having a second surface opposite the first surface. The apparatus also has an isolation wall formed in the multilayer package substrate formed in at least a second and a third layer in the multilayer package substrate and a semiconductor die mounted to the first surface of the multilayer package substrate spaced from and coupled to the first antenna and the second antenna.

### TECHNICAL FIELD

This application relates generally to microelectronic device packages, and more particularly to microelectronic device packages including antennas and semiconductor devices.

### BACKGROUND

Processes for producing microelectronic device packages include mounting a semiconductor die to a package substrate and covering the electronic devices with a dielectric material such as a mold compound to form packaged devices.

Incorporating multiple antennas with semiconductor devices in a microelectronic device package is desirable. Antennas are increasingly used with microelectronic devices and portable devices, such as communications systems, communications devices including 4G, 5G or LTE capable cellphones, tablets, and smartphones. In particular, multiple antennas facilitate using phased array techniques that provide directionality of an outgoing beam or directional sensitivity in receiving signals. Additional applications include microelectronic devices in automotive systems such as radar, navigation and over the air communications systems. Mold compounds used in molded microelectronic devices and some substrate materials used when packaging semiconductor devices have high dielectric constants of about 3 or higher, which can interfere with the efficiency of embedded antennas. Systems using antennas with packaged semiconductor devices therefore often place the antennas on a separate printed circuit board, an organic substrate, spaced from the semiconductor devices. These approaches require additional elements, including expensive printed circuit board (PCB) substrates, which are sometimes used inside a module with semiconductor dies, or sometimes used with packaged semiconductor devices provided spaced apart from the antennas. These solutions are relatively high cost and require substantial device area. Forming microelectronic device packages including efficient and cost-effective antennas within the packages remains challenging.

### SUMMARY

In accordance with an example, an apparatus includes a first antenna and a second antenna formed in a first layer on a first surface of a multilayer package substrate, the multilayer package substrate having layers including patterned conductive portions and dielectric portions, the multilayer package substrate having a second surface opposite the first surface. The apparatus also includes an isolation wall formed in the multilayer package substrate formed in at least a second and a third layer in the multilayer package substrate and a semiconductor die mounted to the first surface of the multilayer package substrate spaced from and coupled to the first antenna and the second antenna.

In accordance with another example, a apparatus includes a first antenna and a second antenna formed in a first layer on a first surface of a multilayer package substrate, the multilayer package substrate having layers including patterned conductive portions and dielectric portions, the multilayer package substrate having a second surface opposite the first surface. The apparatus also includes a semiconductor die mounted to the first surface of the multilayer package substrate spaced from and coupled to the first antenna and the second antenna and a reflector formed in a fourth layer of the multilayer package substrate. The apparatus also includes a top ground layer in the first layer of the multilayer package substrate, the top ground layer having a first opening in which the first antenna is formed and a second opening in which the second antenna is formed and an isolation wall formed in the multilayer package substrate formed in at least a second and a third layer in the multilayer package substrate, wherein the isolation wall extends from the top ground layer to the reflector. The apparatus also includes a first lead coupled to the first antenna and extending from the first antenna and a second lead coupled to the second antenna and extending from the second antenna. The apparatus also includes first lateral reflection walls extending from the top ground layer to the reflector, the first lateral reflection walls surrounding the first antenna except where the first lead extends from the first antenna, wherein a sum of a first distance from the first lateral reflection walls to the first antenna plus a second distance between the top ground layer and the reflector is equal to a wavelength of a frequency which the first antenna is configured to transmit or receive and second lateral reflection walls extending from the top ground layer to the reflector, the second lateral reflection walls surrounding the second antenna except where the second lead extends from the second antenna.

In accordance with another example, an apparatus, includes a first antenna and a second antenna formed in a first layer on a first surface of a multilayer package substrate, the multilayer package substrate having layers including patterned conductive portions and dielectric portions, the multilayer package substrate having a second surface opposite the first surface. The apparatus also includes an isolation wall formed in the multilayer package substrate formed in at least a second and a third layer in the multilayer package substrate and a semiconductor die mounted to the second surface of the multilayer package substrate and coupled to the first antenna and the second antenna.

### BRIEF DESCRIPTION OF THE DRAWINGS

FIG. 1 is a diagram illustrating the operation of a phased array antenna system.

FIGS. 2A-2G (collectively “FIG. 2”) are cross-sections, plan views and perspective views illustrating example arrangements.

FIGS. 3A-3D (collectively “FIG. 3”) are more detailed diagrams of an example antenna arrays.

FIGS. 4A-4C (collectively “FIG. 4”) are plan views of additional arrangements of an antenna array.

FIGS. 5A and 5B (collectively “FIG. 5”) illustrate in two projection views of a semiconductor wafer having semiconductor devices formed on it and configured for flip chip mounting, and an individual semiconductor die for flip chip mounting, respectively.

FIG. 6 illustrates in a cross-sectional view a multilayer package substrate that can be used with the arrangements.

FIGS. 7A-7B (collectively “FIG. 7) illustrate, in a series of cross-sectional views, selected steps for a method for forming a multilayer package substrate that is useful with the arrangements.

FIG. 8 is a graph illustrating the S parameters for the example antenna of FIG. 3, showing simulation results.

FIG. 8 illustrates, in a cross sectional view, an alternative arrangement.

FIG. 9 is a three-dimensional radiation lobe chart of an example antenna.

FIG. 10 is a directivity plot of an example antenna.

FIG. 11 is a graph of crosstalk in an example antenna array.

FIG. 12 is a perspective view of another example antenna array.

FIG. 13 is a graph illustrating the S parameters for the example antenna of FIG. 12.

FIG. 14 is a three-dimensional radiation lobe chart of an example antenna.

FIG. 15 is a directivity plot of an example antenna.

FIG. 16 is a graph of crosstalk in an example antenna array.

FIG. 17 is a perspective view of another example antenna array.

FIG. 18 is a graph of crosstalk in an example antenna array.

FIG. 19 is a graph comparing the crosstalk in non-adjacent antennas in the arrangements of FIG. 3 and FIG. 17.

FIG. 20 is a graph comparing the crosstalk in non-adjacent antennas in the arrangements of FIG. 12 and FIG. 17.

### DETAILED DESCRIPTION

In the drawings, corresponding numerals and symbols generally refer to corresponding parts unless otherwise indicated. The drawings are not necessarily drawn to scale.

In this description, the term “coupled” may include connections made with intervening elements, and additional elements and various connections may exist between any elements that are “coupled.” Also, as used herein, the terms “on” and “over” may include layers or other elements where intervening or additional elements are between an element and the element that it is “on” or “over.”

The term “semiconductor die” is used herein. A semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor die can be an integrated circuit with hundreds, or thousands of transistors coupled to form a functional circuit, for example a microprocessor or memory device.

The term “microelectronic device package” is used herein. A microelectronic device package has at least one semiconductor die electrically coupled to terminals and has a package body that protects and covers the semiconductor die. The microelectronic device package can include additional elements, in some arrangements an integrated antenna is included. Passive components such as capacitors, resistors, and inductors or coils can be included. In some arrangements, multiple semiconductor dies can be packaged together. For example, a power metal oxide semiconductor (MOS) field effect transistor (FET) semiconductor die and a logic semiconductor die (such as a gate driver die or a controller die) can be packaged together to from a single packaged electronic device. The semiconductor die is mounted to a package substrate that provides conductive leads, a portion of the conductive leads form the terminals for the packaged device. The semiconductor die can be mounted to the package substrate with a device side surface facing away from the substrate and a backside surface facing and mounted to a die pad of the package substrate. In wire bonded semiconductor device packages, bond wires couple conductive leads of a package substrate to bond pads on the semiconductor die. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the semiconductor device package.

The term “package substrate” is used herein. A package substrate is a substrate arranged to receive a semiconductor die and to support the semiconductor die in a completed semiconductor device package. Package substrates useful with the arrangements include conductive lead frames, which can be formed from copper, aluminum, stainless steel, steel and alloys such as Alloy 42 and copper alloys. The lead frames can include a die pad with a die side surface for mounting a semiconductor die, and conductive leads arranged near and spaced from the die pad for coupling to bond pads on the semiconductor die using wire bonds, ribbon bonds, or other conductors. The lead frames can be provided in strips or arrays. The conductive lead frames can be provided as a panel with strips or arrays of unit device portions in rows and columns. Semiconductor dies can be placed on respective unit device portions within the strips or arrays. A semiconductor die can be placed on a die pad for each packaged device and die attach or die adhesive can be used to mount the semiconductor dies to the lead frame die pads. In wire bonded packages, bond wires can couple bond pads on the semiconductor dies to the leads of the lead frames. The lead frames may have plated portions in areas designated for wire bonding, for example silver plating can be used. After the bond wires are in place, a portion of the package substrate, the semiconductor die and at least a portion of the die pad can be covered with a protective material such as a mold compound.

The term “multilevel package substrate” is used herein. A multilevel package substrate is a substrate that has multiple conductor levels including conductive traces, and which has vertical conductive connections extending through the dielectric material between the conductor levels. In an example arrangement, a multilevel package substrate is formed by plating a patterned conductor level and then covering the conductor with a layer of dielectric material. Grinding can be performed on the dielectric material to expose portions of the layer of conductors. Additional plating layers can be formed to add additional levels of conductors, some of which are coupled to the prior layers by vertical connectors, and additional dielectric material can be deposited at each level and can cover the conductors. By using an additive or build up manufacturing approach, and by performing multiple plating steps, molding steps, and grinding steps, a multilayer package substrate is formed with an arbitrary number of layers. In an example arrangement, copper conductors are formed by plating, and a thermoplastic material can be used as the dielectric material.

In packaging microelectronic and semiconductor devices, mold compound may be used to partially cover a package substrate, to cover components, to cover a semiconductor die, and to cover the electrical connections from the semiconductor die to the package substrate. This molding process can be referred to as an “encapsulation” process, although some portions of the package substrates are not covered in the mold compound during encapsulation, for example terminals and leads are exposed from the mold compound. Encapsulation is often a compressive molding process, where thermoset mold compound such as resin epoxy can be used. A room temperature solid or powder mold compound can be heated to a liquid state and then molding can be performed by pressing the liquid mold compound into a mold through runners or channels. Transfer molding can be used. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together.

After the molding, the individual packaged devices are cut from each other in a sawing operation by cutting through the mold compound and package substrate in saw streets formed between the devices. Portions of the package substrate leads are exposed from the mold compound package to form terminals for the packaged semiconductor device.

The term “scribe lane” is used herein. A scribe lane is a portion of semiconductor wafer between semiconductor dies. Sometimes in related literature the term “scribe street” or “scribe line” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets. The two groups are normal to each other, and the saw will traverse the molded electronic devices in two different directions to cut apart the packaged electronic devices from one another in the array.

The term quad flat no-lead (QFN) is used herein for a type of electronic device package. A QFN package has conductive leads that are coextensive with the sides of a molded package body, and in a quad package the leads are on four sides. Alternative flat no-lead packages may have leads on two sides or only on one side. These can be referred to as small outline no-lead or SON packages. No-lead packaged electronic devices can be surface mounted to a board. Leaded packages can be used with the arrangements where the leads extend away from the package body and are shaped to form a portion for soldering to a board. A dual in line package (DIP) can be used with the arrangements. A small outline package (SOP) can be used with the arrangements. Small outline no-lead (SON) packages can be used, and a small outline transistor (SOT) package is a leaded package that can be used with the arrangements. Leads for leaded packages are arranged for solder mounting to a board. The leads can be shaped to extend towards the board, and form a mounting surface. Gull wing leads, J-leads, and other lead shapes can be used. In a DIP package, the leads end in pin shaped portions that can be inserted into conductive holes formed in a circuit board, and solder is used to couple the leads to the conductors within the holes.

In the arrangements, a microelectronic device package includes a semiconductor die mounted to a multilayer package substrate. The multilayer package substrate has a device side surface, a semiconductor die mounted on a portion of the device side surface, and an antenna formed spaced from the die portion. In an example arrangement the semiconductor die will be mounted beside, or side by side, with respect to an antenna formed on the device side surface. In the multilayer package substrate, the antenna can be formed in a conductive layer at or near the device side surface of the multilayer package substrate, for example as a patterned plated conductor layer of the multilayer package substrate. Another layer of the multilayer package substrate can have a reflector patterned in a conductor beneath the antenna pattern, to increase efficient transmission by the antenna by reflecting radiated energy back towards the antenna and away from the device side surface of the multilayer package substrate. A semiconductor die mounted to the device side surface of the multilayer package substrate can be coupled to the antenna by conductive traces formed in conductor layers of the multilayer package substrate. In one example, the semiconductor die is flip chip mounted to the multilayer package substrate. In an alternative example, a semiconductor die mounted facing away from the device side surface of the multilayer package substrate and is wire bonded to conductive traces on the multilayer package substrate.

The semiconductor die used in the arrangements can be a monolithic millimeter wave integrated circuit (MMIC). The MMIC can be a transmitter, receiver, transceiver, or a component in a system for transmitting or receiving signals such as an amplifier, encoder, filter, or decoder. The semiconductor die can be provided as multiple semiconductor dies or as components mounted to the multilayer package substrate, to form a system. Additional passive components can be mounted to the multilayer package substrate.

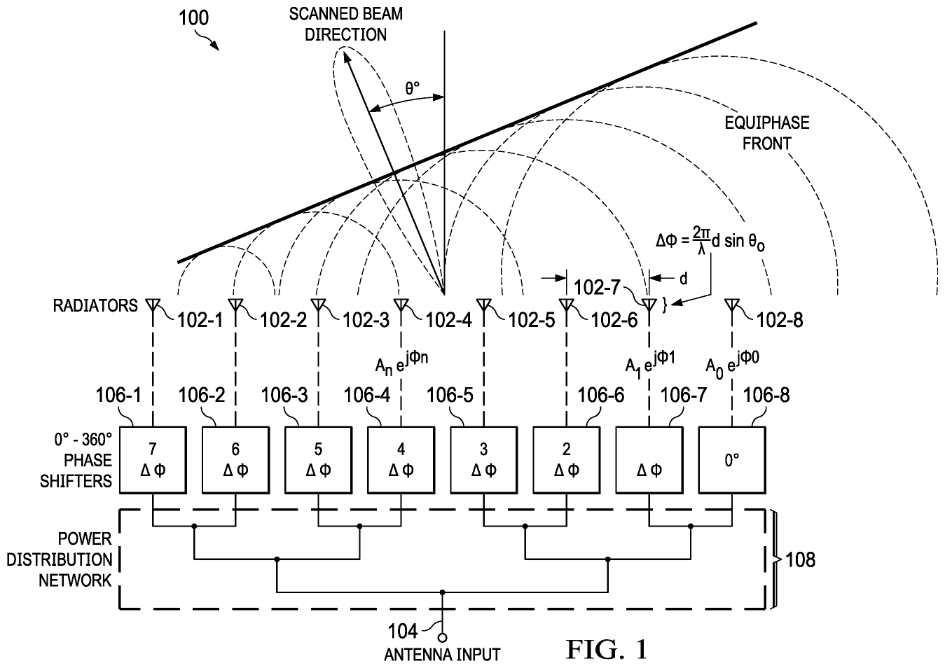

FIG. 1 is a diagram illustrating the operation of a phased array antenna system. Phased array 100 is a linear array of eight antennas 102-1 through 102-8. Antenna input 104 feeds eight phase shifters 106-1 through 106-8 using power distribution network 108. Phase shifters 106-1 through 106-8 are controlled using control circuitry (not show) to have a phase shift selected between 0° and 360°. By reversing the configuration to provide a receiver instead of an antenna input and phase shifting the received signals at each antenna, the phased array can receive with directional sensitivity. The phase shift for each phase shifter is selected so that interference between the signals on each antenna constructively interfere in a selected direction. In this example, the selected direction is an angle θ from line perpendicular to the phased array. In the example of linear phased array of FIG. 1, the phase shifter 106-8 has a shift of 0°. The next phase shifter 106-7 has a shift of Δϕ, where Δϕ is determined by Equation (1):

$$Δ ϕ = \frac{2 π}{λ} d sin θ \qquad ( 1 )$$

where θ is the angle of the desired directionality of the phased array, λ, is the wavelength of the transmitted or received signal, and d is the distance between the antennas in the phased array. The next phase shift on antenna 106-6 is then 2Δϕ and so on. The signal at each antenna can be summarized as in Equation (2)

Aₙe^{jϕn} (2)

where Aₙ is the amplitude on the n^{th} antenna, and ϕ is equal to Δϕ. The example of FIG. 1 is a simple linear example with eight antennas. Phased arrays may have any configuration, with a common configuration being a square of thirty-six, forty-nine, sixty-four, or more antennas. These more complex arrays can provide improved directionality of the beam. The mathematics of these more complex arrays becomes significantly more complex, but the operating principle remains the same. That is, phased arrays are useful for sending directional beams or receiving with directional sensitivity.

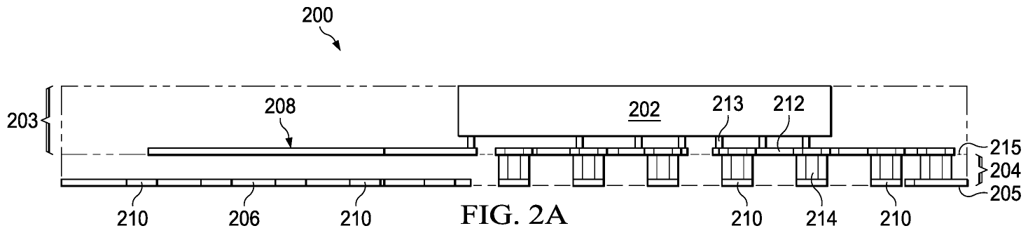

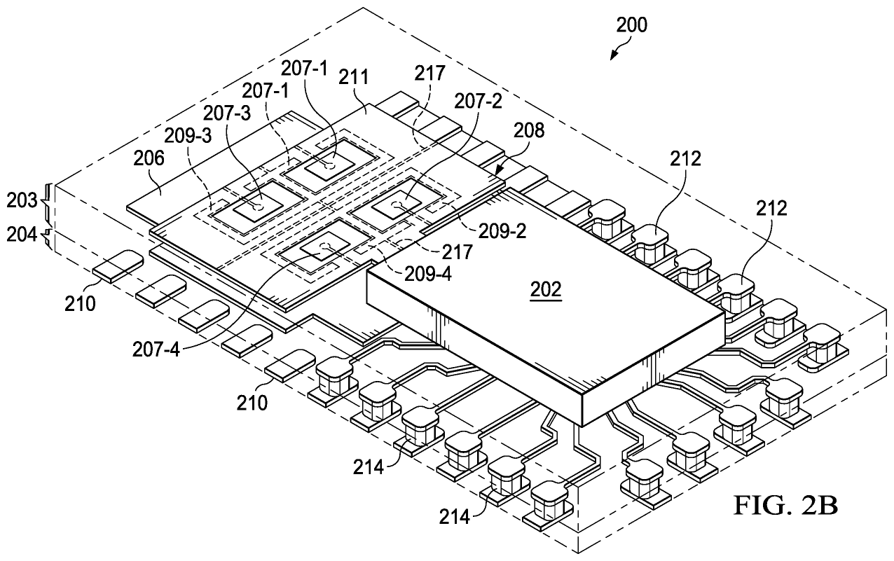

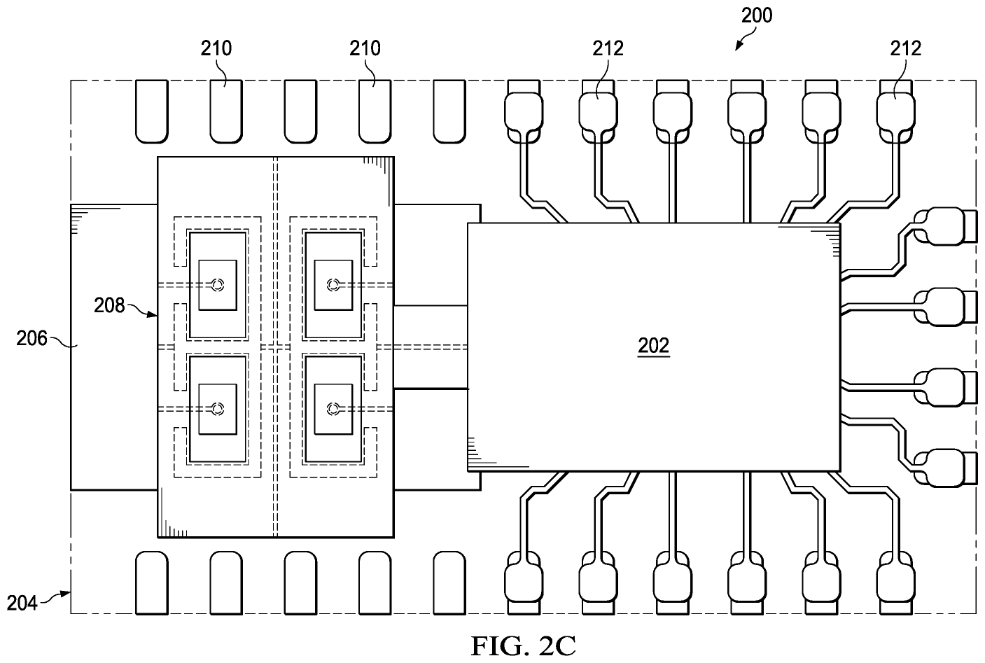

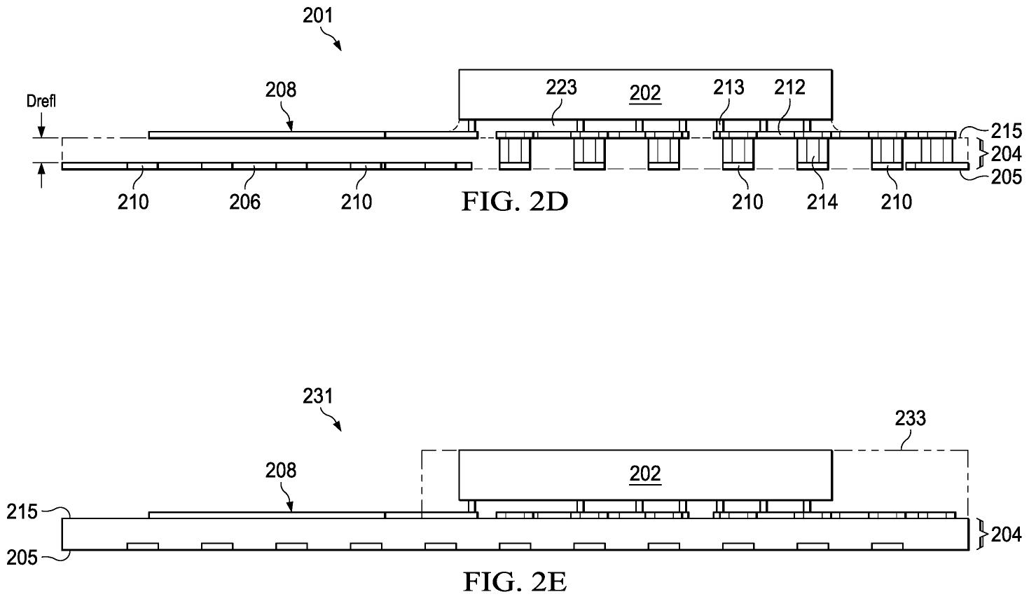

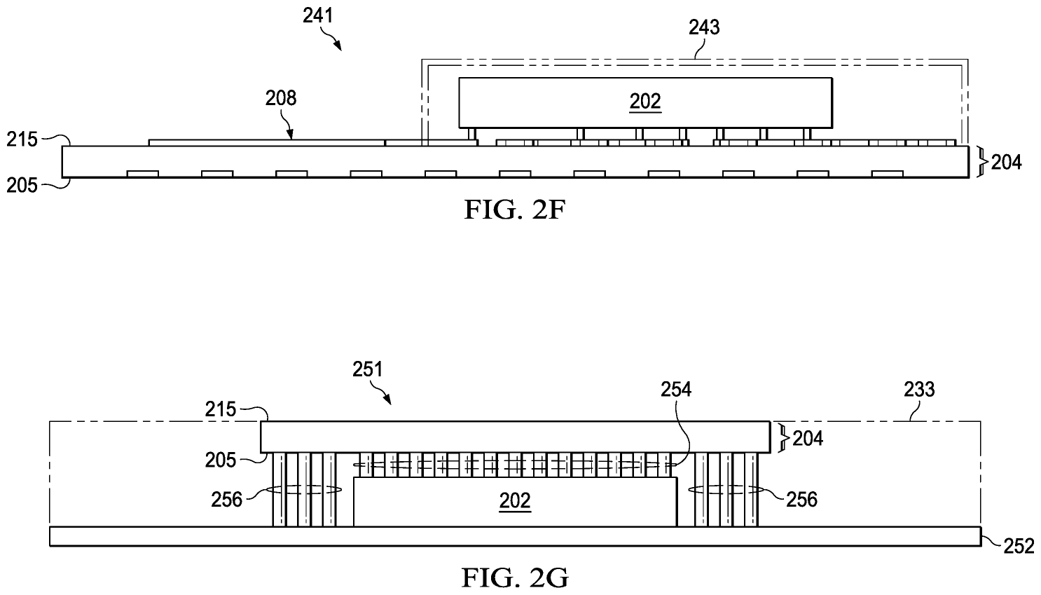

FIGS. 2A-2G (collectively “FIG. 2) are cross-sections, plan views and perspective views illustrating example arrangements. FIG. 2A illustrates, in a cross-sectional view, a microelectronic device package 200, in an example arrangement using a quad flat no lead (QFN) package. QFN packages are one type of package that is useful with the arrangements. Other package types including leaded and other no lead packages can be used. The microelectronic device package 200 includes a multilayer package substrate 204. Terminals 210 are formed of a conductor material on a board side surface 205 (the bottom surface as the arrangement as oriented in FIG. 2A) of the microelectronic device package 200. Vertical connectors 214 extend from terminals 210 through layers of dielectric material of the multilayer package substrate 204 to a device side surface 215 of the multilayer package substrate 204, where leads 212 are formed of conductors of a conductive layer of the multilayer package substrate. A semiconductor die 202 is mounted to the device side surface 215 of the multilayer package substrate 204. The semiconductor die 202 in the illustrated example is flip chip mounted, so that an active surface of the semiconductor die 202 is oriented facing the device side surface of the multilayer package substrate 204. Conductive post connects 213 extend from the semiconductor die 202 to leads 212 and make electrical connections between semiconductor die 202 and multilayer package substrate 204.

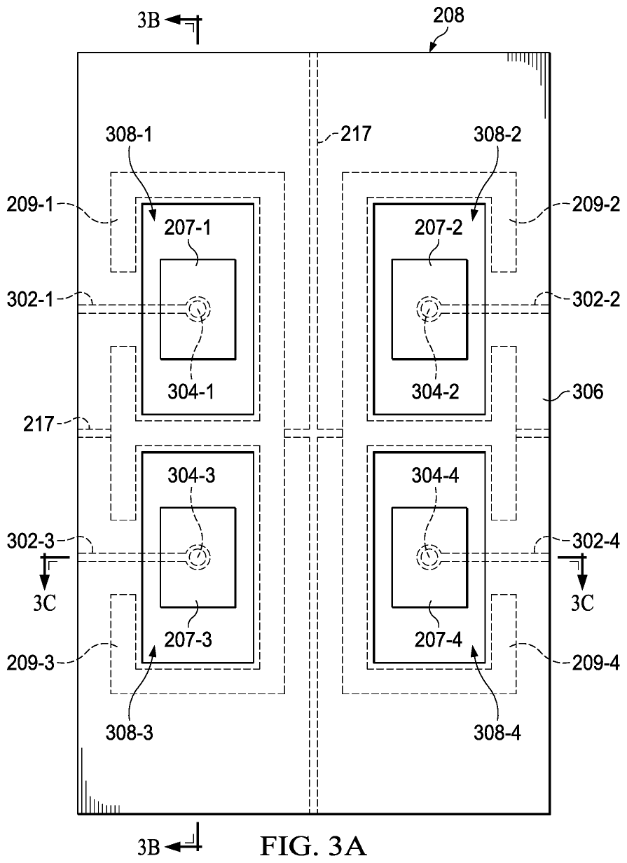

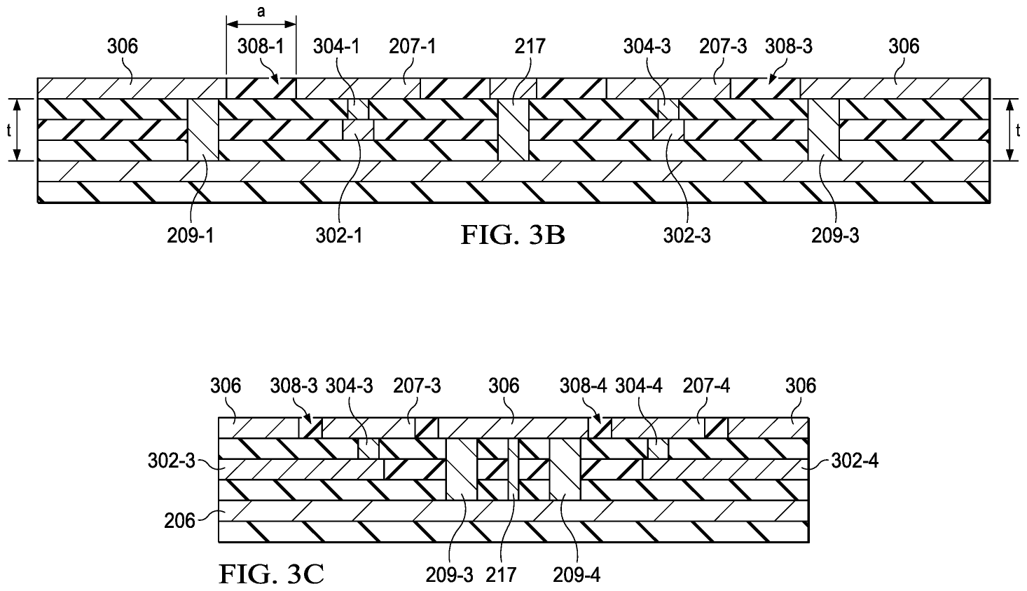

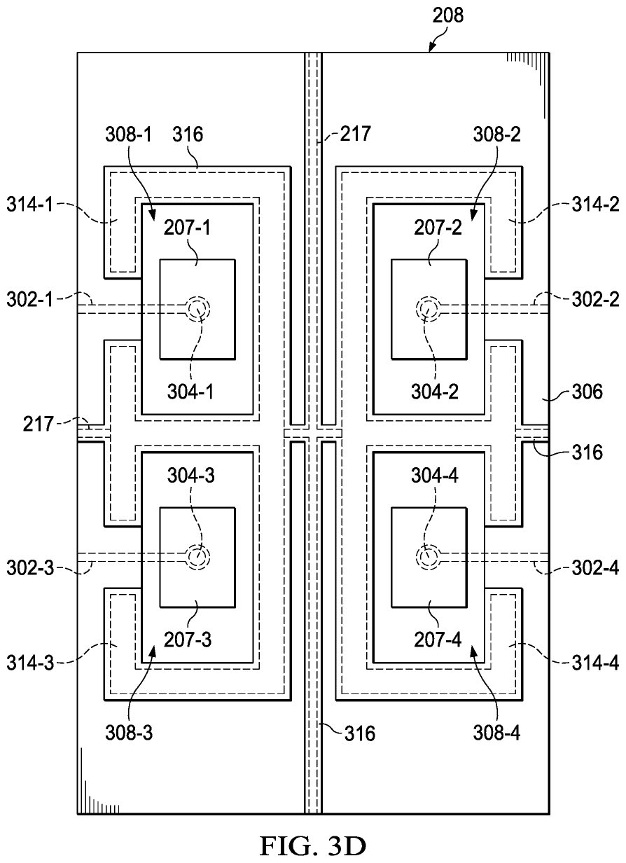

An antenna array 208 is formed of a first conductor layer on the device side surface 215 of the multilayer package substrate 204. In this example, the antenna array 208 includes four antennas 207-1 through 207-4. The structures of antennas 207-1 through 207-4 are more fully explained with regard to FIG. 3 hereinbelow. Antenna array 208 is coupled to the semiconductor die 202 by conductive post connects 213 mounted to leads 212. The device side surface 215 of the multilayer package substrate 204 and the semiconductor die 202 are covered with mold compound 203. A reflector 206 is formed in another conductor layer of the multilayer package substrate 204 and is positioned beneath the antenna array 208 (as the elements are oriented in FIG. 2A), and in a conductor layer that is formed closer to or at the board side surface 205 of the multilayer package substrate 204. The reflector 206 is aligned with and spaced from the antenna array 208 by the dielectric material of the multilayer package substrate 204.

In FIG. 2B, the microelectronic device package 200 is illustrated in a projection view and includes mold compound 203 covering the device side surface 215 of the multilayer package substrate 204 and surrounding and protecting the semiconductor die 202 and the device side surface of the multilayer package substrate 204. Terminals 210 on the board side surface 205 are configured for mounting to a system board, for example a printed circuit board. Leads 212 are formed on the device side surface 215 of the multilayer package substrate 204 can be formed of the same material as the conductors in antenna array 208, for example, copper, gold, aluminum, silver, or an alloy of these. Protective plating layers such as palladium, nickel, gold, or multiple layers of these can be form on the phase antenna array 208. In the illustrated example of FIG. 2B, semiconductor die 202 is flip chip mounted to the device side surface 215 of the multilayer package substrate 204, and has conductive post connects (not visible in FIG. 2B, see FIG. 2A) extending from an active surface of the semiconductor die 202 bonded to the device side surface of the multilayer package substrate 204. Mold compound 203 or other protective material is shown overlying the antenna array 208 and surrounding the semiconductor die 202. In an alternative arrangement, the mold compound 203 can cover the semiconductor die 202. In the arrangement illustrated in FIGS. 2A-2C, antenna array 208 is covered by the mold compound 203, and signals radiated from or received by the antenna array 208 traverse the mold compound 203.

FIG. 2B illustrates the microelectronic device package 200 with the antenna array 208 formed on the device side surface of the multilayer package substrate 204 in multiple conductor layers. The semiconductor die 202 is shown mounted on the device side surface of the multilayer package substrate 204 in a side-by-side orientation with respect to the antenna array 208. Although not shown in the illustration for simplicity of explanation, additional components such as passives or additional semiconductor devices can be mounted to the device side surface of the multilayer package substrate 204. Leads 212 are formed on the device side surface of the multilayer package substrate 204 and couple the semiconductor die 202 to vertical connectors 214, which are conductors formed of the intervening conductive layers of the multilayer package substrate 204 that extend through dielectric material to the terminals 210. The reflector 206 is formed beneath and aligned with the antenna array 208. Antenna array 208 is formed in first, second and third conductor layers (as further explained hereinbelow with regard to FIG. 3), and reflector 206 is formed in another conductor layer of the multilayer package substrate 204 and can be on the board side surface (the lowest conductor level) or can be at another conductor level of the multilayer package substrate 204, depending on the number of conductor levels in the multilayer package substrate 204.

The example antenna array 208 in FIG. 2B is an array of four antennas 207-1 through 207-4. In this example, each antenna is partially surrounded by reflection walls 209-1 through 209-4, respectively. Reflection walls 209-1 through 209-4 extend from reflector 206 to top conductor 211. In addition, isolation walls 217 separate antennas 207-1 through 207-4. Isolation walls 217 also extend from reflector 206 to top conductor 211. In an alternative arrangement, additional antenna shapes can be used. In yet another alternative arrangement, additional antennas can be formed to increase the gain and directionality of the antenna array 208. Antenna array 208 can be formed of the conductor layers on the device side of the multilayer package substrate 204, for example antenna array 208 can be formed of copper or gold or alloys. Other conductive materials compatible with plating processes can be used, including silver and aluminum. The reflector 206 is formed in another conductor layer of the multilayer package substrate 204 and can be formed of the same material or another conductor material, for example reflector 206 can be formed of copper or gold. The dielectric material of the multilayer package substrate 204 can be a thermoplastic or a thermoset material. An example thermoplastic material is ABS (Acrylonitrile Butadiene Styrene) Alternative dielectric materials include thermoplastics such as ASA (Acrylonitrile Styrene Acrylate), thermoset mold compound including epoxy resin, epoxies, resins, or plastics. A mold compound 203 is shown overlying antenna array 208 and protecting the semiconductor die 202. Mold compound 203 can be a thermoset mold compound of epoxy resin, another epoxy, a resin, or plastic.

FIG. 2C illustrates the microelectronic device package 200 in a plan or top view. In FIG. 2C, the microelectronic device package 200 includes multilayer package substrate 204, with antenna array 208 formed in the first conductor layer on a device side surface, and reflector 206 formed in another conductor layer beneath and spaced from the antenna array 208. Terminals 210 on the board side surface are configured for mounting to a system board, for example for surface mounting to a printed circuit board. Leads 212 are formed on the device side surface of the multilayer package substrate 204 can be formed of the same material as antenna array 208, for example, copper or gold or an alloy of these. The semiconductor die 202 is flip chip mounted to the device side surface of the multilayer package substrate 204, and has conductive post connects (not visible in FIG. 2C, see conductive post connects 213 in FIG. 2A) extending from an active surface of the semiconductor die 202 configured for bonding to the device side surface of the multilayer package substrate 204. In the arrangement of FIGS. 2A-2C, the antenna array 208 is covered by a mold compound 203, and signals radiated from the antenna array 208 must traverse the mold compound 203.

The arrangement shown in FIGS. 2A-2C can be formed using additive manufacturing, or build up processing, to form the multilayer package substrate including the antenna array 208 and the reflector 206. As is further described below, by using a series of plating, molding, and grinding steps, successive layers of trace level conductors, vertical connections, and dielectric can be formed, and these steps can be repeated to form the multilayer package substrate. The antenna array 208 can be formed by forming a pattern on a rectangular portion of the first conductor layer. Because the vertical connections are formed using an additive process, and then dielectric material is molded over the vertical connections, the need for drilling precise via holes, and the need to plate or fill the via holes with conductors, is eliminated, so the multilayer package substrate is cost effective (when compared to organic substrates such as printed circuit boards.) By mounting the semiconductor die on the multilayer package substrate spaced from and coupled to the antenna array using existing flip chip or wire bonding connections, a reliable and cost effective microelectronic device package including an antenna is provided by use of the arrangements.

FIG. 2D illustrates an alternative arrangement for a microelectronic device package 201 in a cross section. The multilayer package substrate 204 is configured as in FIGS. 2A-2C, and the antenna array 208 is formed in the first, second and third conductor layers on a device side surface 215 of the multilayer package substrate 204. The reflector 206 is formed in another conductor layer nearer to, or on the board side surface of the multilayer package substrate 204 and spaced from the antenna array 208. The semiconductor die 202 is shown flip chip mounted to the device side surface 215 of the multilayer package substrate 204. Underfill material 223 such as a resin or epoxy, or a glob top mold compound which is applied as a gel or liquid, can be flowed beneath the semiconductor die 202 after mounting the semiconductor die 202, to protect the conductive post connects 213 and solder connections to leads 212.

Comparing the arrangements of FIG. 2D and FIGS. 2A-2C, in FIG. 2D the mold compound (see mold compound 203 in FIGS. 2A-2B) is not provided over the device side surface of the multilayer package substrate, so that the antenna array 208 has a surface exposed to air. In this arrangement, signals radiated from the antenna array 208 do not traverse the mold compound (see mold compound 203 in FIG. 2A) and are instead transmitted in air.

FIG. 2D also illustrates a spacing distance labeled Dref1 between the antenna array 208 and the reflector 206 in one arrangement. In the arrangements, the antenna array (208 in FIG. 2D) is configured to radiate signals upwards away from the device side surface of the multilayer package substrate 204. When energy is applied to the antennas 207-1 through 207-4 of antenna array 208, the energy radiates in all directions from each antenna, including through the multilayer package substrate 204 towards the reflector 206. Because as the signal energy travels, the phase shifts, and because the reflector 206 will cause a λ/2 phase shift, where λ is the wavelength of the signal, the distance Dref1 can be adjusted to be approximately λ/4, so that the energy transmitted to the reflector, reflected by the reflector, and returned to the antenna 207-X traverses a phase shift of λ/4+λ/2 +λ/4, or λ, and the reflected energy from reflector 206 arrives at the antenna 207-X in phase with the energy being transmitted upwards from the antenna 207-X, adding to the gain of the signal using of constructive interference. By using different layers of the multilayer package substrate 204 to form the reflector 206, the distance Dref1 can be altered so as to increase the efficiency of the antenna array 208 and reflector 206. This same alteration can be used with any of the arrangements. The thickness of the multilayer package substrate 204 can be varied to vary the distance Dref1. Note that the wavelength λ, in the multilayer package substrate differs from the wavelength in air because it depends on the dielectric constant of the material the signal is traversing, simulation of the signal propagation in the selected dielectric material can be used to determine the proper spacing distance Dref1.

FIGS. 2E and 2F illustrate, in cross sections, additional arrangements based on the arrangement of FIG. 2D. Note that in both FIGS. 2E and 2F, certain elements are not shown for simplicity of illustration, for example the reflector 206 is not shown in FIGS. 2E-2F, however it is present in these arrangements. In FIG. 2E, an arrangement for a microelectronic device package 231 with antenna array 208 includes mold compound 233 selectively formed over a portion of the device side surface 215 of the multilayer package substrate 204.

In FIG. 2E, mold compound 233 covers the semiconductor die 202 and a portion of the multilayer package substrate 204, but does not cover the antenna array 208, so that energy transmitted from or received by the antenna array 208 traverses only air and does not traverse the mold compound 233. The mold compound 233 can be selectively formed over a portion of the multilayer package substrate 204 using film assisted transfer molding, where a film is used to line a mold tool, and the film and mold tool are configured to contain the mold compound transferred into the mold around the semiconductor die 202, and leaving the antenna array 208 without mold compound formed over it, so that signals from the antenna array 208 are radiated into the air, and do not traverse any part of mold compound 233.

In FIG. 2F, an alternative arrangement for a microelectronic device package 241 includes a metallic or ceramic shield 243 formed around the semiconductor die 202 and covering a portion of the device side surface 215 of the multilayer package substrate 204, but not covering the antenna array 208, which is configured to radiate electromagnetic energy into the air. The shield 243 can be a mesh or grid and may be arranged as a Faraday cage or electronic field shield, to reduce noise or unwanted coupling between the antenna array 208 and the semiconductor die 202.

FIG. 2G is another alternative arrangement. In microelectronic device package 251, semiconductor die 202 is not flipped and conductive post connects 254 on the top of semiconductor die (as oriented in FIG. 2G) couple to pads on the bottom surface 205 of multilevel package substrate 204, which is above semiconductor die 202. This is sometimes called a “dead bug” arrangement because the semiconductor die with conductive post connects resembles a bug on its back. A phased antenna array (not visible in this figure) is formed in top surface 215 of multilevel package substrate 204. Mold compound 233 encapsulates the device package 251. Conductive post connects 256 couple multilevel package substrate 204 to a second multilevel package substrate 252 to facilitate mounting to a pc board or other substrate.

In the arrangements, a semiconductor device is mounted to a device side surface of a multilayer package substrate. In forming the arrangements, the semiconductor devices can be formed independently of the multilayer package substrate, so that methods for forming the semiconductor device, and the multilayer package substrate, can be performed at different times, and at different locations, then the components can be assembled together to complete the arrangements.

FIGS. 3A-3D (collectively “FIG. 3”) are more detailed diagrams of an example antenna array 208. FIG. 3A is a plan view of antenna array 208. Antennas 207-1 through 207-4 are coupled to input leads 302-1 through 302-4, respectively, via posts 304-1 through 304-4, respectively. Leads 302-1 through 302-4 have an impedance (e.g., 10-100 Ω) selected to provide good transfer of high frequency signals (e.g., 10-200 GHz). Each of leads 302-1 through 302-4 routs through multilayer package substrate 204 (FIG. 2) to either a conductive post connect 213 or a terminal 210 (FIG. 2). Reflector 206 (FIG. 2) is behind the structure shown in FIG. 3A. Top ground layer 306 covers the top of antenna array 208 except at openings 308-1 through 308-4 where antennas 207-1 through 207-4 are positioned, respectively. Isolation walls 217 extend from top ground layer 306 to reflector 206. Isolation walls 217 are conductive portions of each layer of the multilayer package substrate between top ground layer 306 and reflector 206. Thus, isolation walls 217 conductively couple top ground and reflector 206 and help limit crosstalk between antennas 207-1 and 207-4. In arrangements, either or both of top ground layer 306 and reflector 206 are coupled to ground or another reference potential. In addition, each of antennas 207-1 through 207-4 is surrounded by lateral reflection walls 209-1 through 209-4, respectively, except at an opening to allow for leads 302-1 through 302-4, respectively. Lateral reflection walls 209-1 through 209-4 also extend from reflector 206 to top ground layer 306.

FIG. 3B shows a cross section of antenna array 208 along the cut line indicated in FIG. 3A. In the example of FIGS. 2E and 2F, the distance from the antennas 207-1 through 207-4 is Dref1. To provide perfect constructive interference with that arrangement, Dref1 must be 214. However, that is not always possible. For example, if the frequency transmitted by antennas 207-1 through 207-4 is 100 GHz, λ, is equal to about 3 mm or 3,000 μm. Thus, 214 is about 750 μm. In compact arrangements, the total thickness of multilayer package substrate 204 is 200 μm. Thus, it is not possible to provide a Dref1 of 214 in these compact multilayer package substrates.

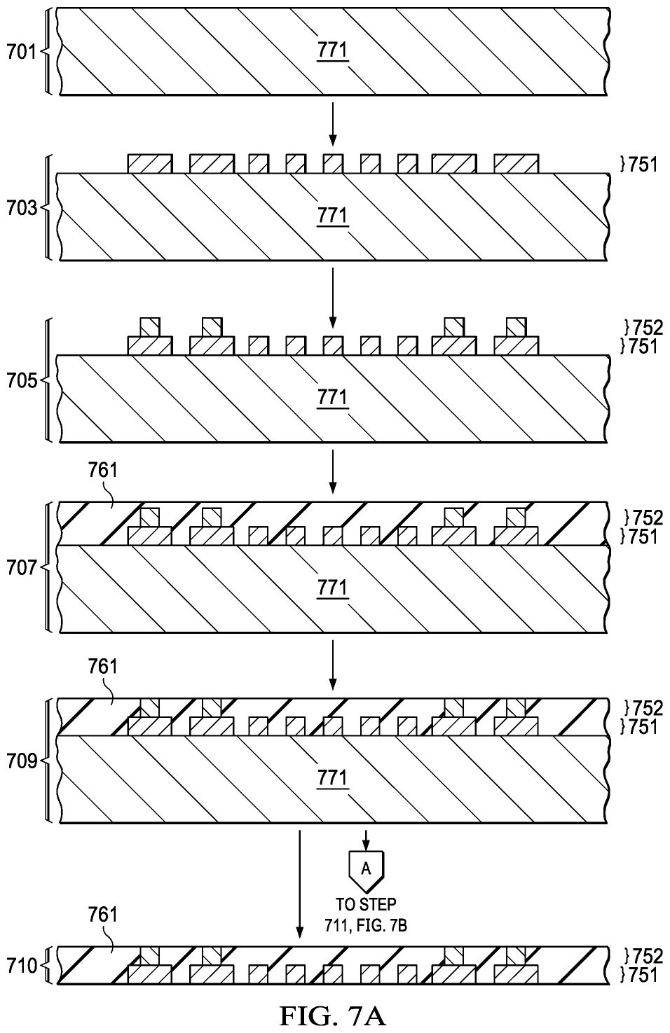

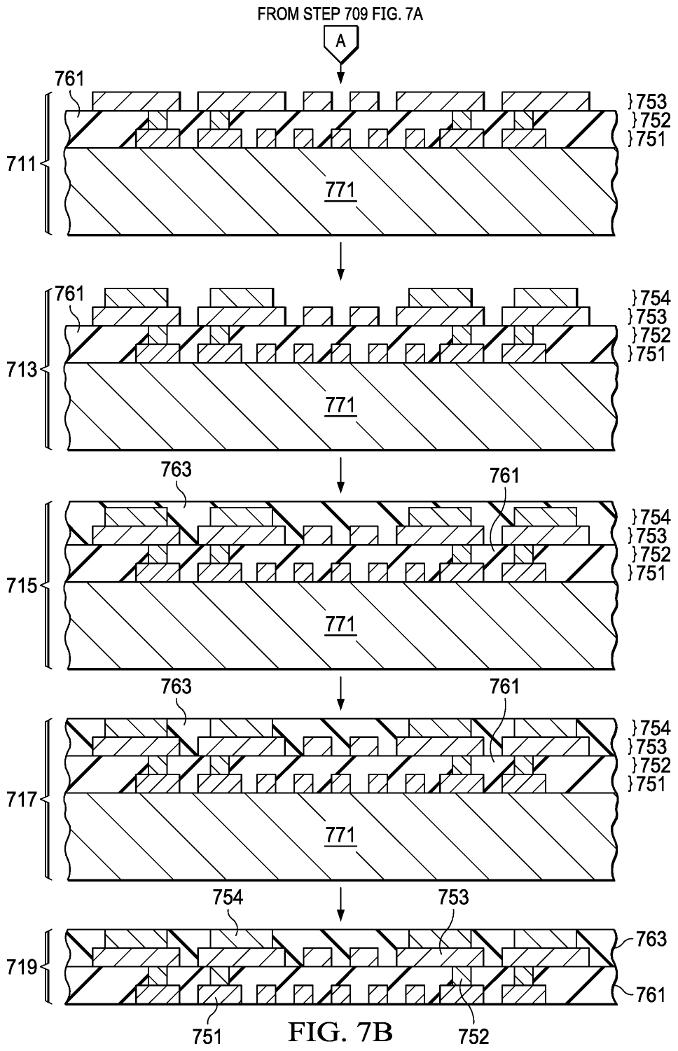

To compensate for the lack of positive interference directly from reflector 206 in compact multilayer package substrates, the arrangement of FIG. 3 includes lateral reflection walls 209-1 through 209-4. Using computer simulations, it has been determined that using a lateral reflection wall (e.g. lateral refection wall 313-1) spaced from a patch antenna (that is, an antenna with a major plane perpendicular to the primary direction of travel of the transmitted wave) by a distance a with a distance from the bottom of the antenna to the reflector 206 of t will efficiently transmit a signal if the sum of t+a is approximately equal to the λ/4. Of note, λ, in this case is determined using the speed of light through the insulating material under the antenna 207-X (see discussion regarding FIGS. 6-7 hereinbelow). The insulating material has a refractive index less than one and the speed of light through a material is r*c, where r is the refractive index and c is the speed of light in a vacuum. Because

$$λ = \frac{rc}{f}$$

for a given frequency, λ, will be smaller through the insulating material than in a vacuum or air (which has a refractive index nearly equal to a vacuum, which is 1). For example, if t=200 μm, f=100 GHz, and r=0.8, then

$$λ = \frac{rc}{f} = 2400 µm .$$

Thus, distance a must be 400 μm (214=2400/4 μm=600 μm=t+a, so a=600 μm-200 μm). FIG. 3C is a cross section of antenna array 208 along the cut line indicated in FIG. 3A.

FIG. 3D is a plan view of another arrangement. Antennas 207-1 through 207-4 are coupled to input leads 302-1 through 302-4, respectively, via posts 304-1 through 304-4, respectively. Leads 302-1 through 302-4 have an impedance (e.g., 10-100 Ω) selected to provide good transfer of high frequency signals (e.g., 10-200 GHz). Each of leads 302-1 through 302-4 routs through multilayer package substrate 204 (FIG. 2) to either a conductive post connect 213 or a terminal 210 (FIG. 2). Reflector 206 (FIG. 2) is behind the structure shown in FIG. 3A. Top ground layer 306 covers the top of antenna array 208 except at openings 308-1 through 308-4 where antennas 207-1 through 207-4 are positioned, respectively. Isolation walls 217 extend from top ground layer 306 to reflector 206. Isolation walls 217 are conductive portions of each layer of the multilayer package substrate between top ground layer 306 and reflector 206. Thus, isolation walls 217 conductively couple top ground and reflector 206 and help limit crosstalk between antennas 207-1 and 207-4. In arrangements, either or both of top ground layer 306 and reflector 206 are coupled to ground or another reference potential. In addition, each of antennas 207-1 through 207-4 is surrounded by lateral reflection walls 209-1 through 209-4, respectively, except at an opening to allow for leads 302-1 through 302-4, respectively. Lateral reflection walls 209-1 through 209-4 also extend from reflector 206 to top ground layer 306. In addition to these elements that are provided in the arrangement of FIG. 3A, includes elevated traces 316 in an additional conductive layer above the isolation walls 217 and lateral reflection walls 209-1 through 209-4. Elevated traces 316 provide additional directionality of the signal provided by antennas 207-1 through 207-4 and an additional barrier against crosstalk between antennas 207-1 through 207-4.

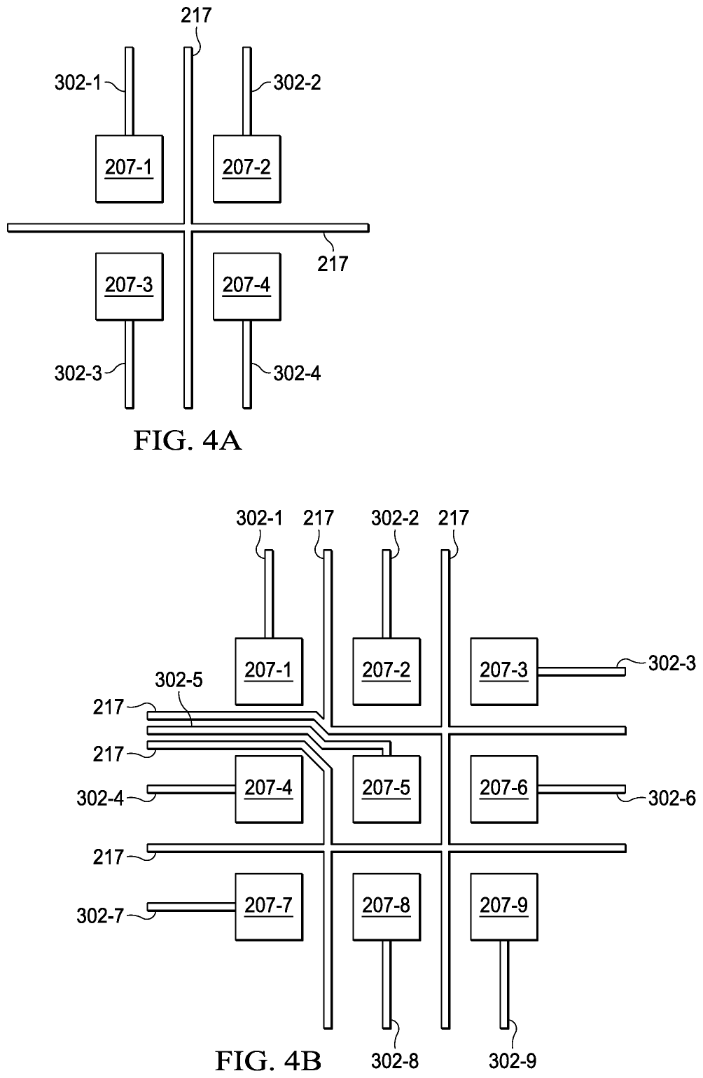

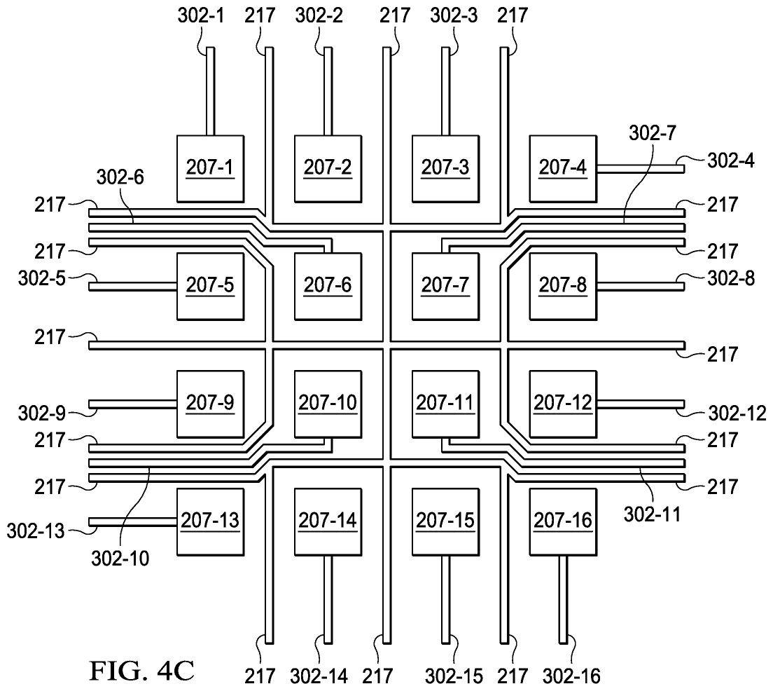

FIGS. 4A-4C (collectively “FIG. 4”) are plan views of additional arrangements of antenna array 208. FIG. 4A shows a two-by-two array of four antennas 207-1 through 207-4. Isolation walls 217 separate antennas 207-1 through 207-4 and leads 302-1 through 302-4 from each other to diminish crosstalk. Reflection walls like lateral reflection walls 209-1 through 209-4 are not shown in FIG. 4 but may optionally be included with one reflection wall partially surrounding each antenna. FIG. 4B shows a three-by-three array of nine antennas 207-1 through 207-9 with isolation walls 217 separating antennas 207-1 through 207-9 and leads 212. FIG. 4C shows a four-by-four array of sixteen antennas 207-1 through 207-16 with isolation walls 217 separating antennas 207-1 through 207-15 and leads 212. There is no theoretical limit to the number of antennas in an array. The layouts of FIG. 4 are only included as examples. Other examples may include hundreds of antennas. It is an advantage to include as many antennas as practicable to allow for more precise beam forming. In addition, the configuration of antennas need not be square, but can be any configuration depending on the application to which the antennas are applied.

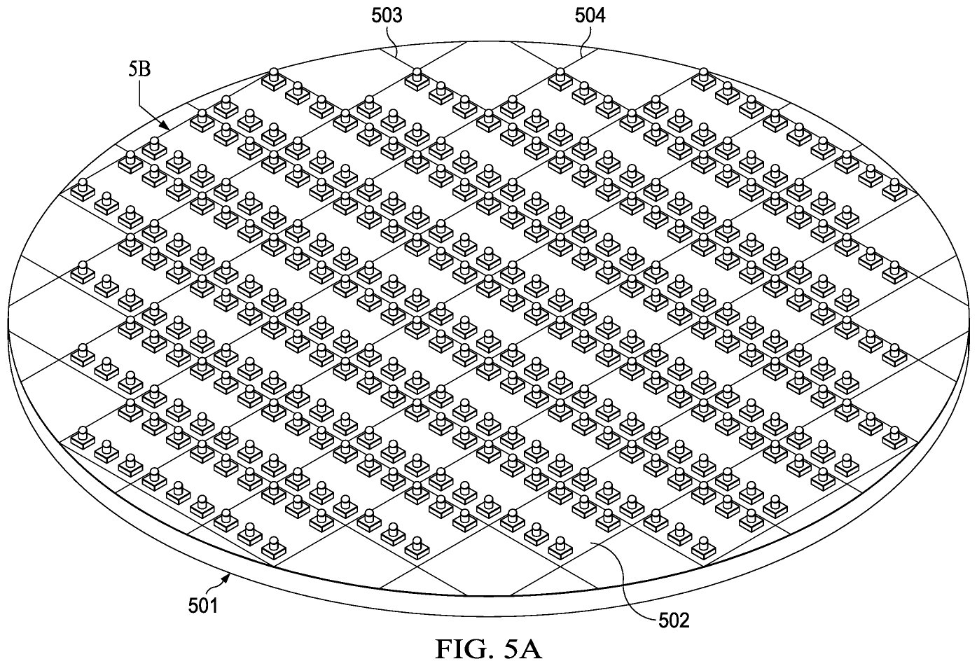

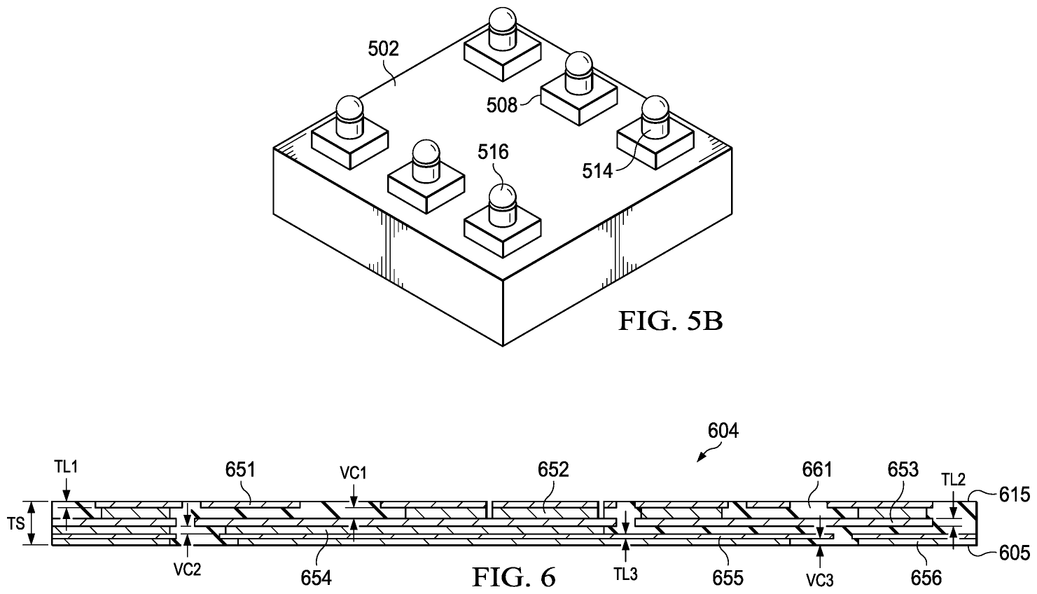

FIGS. 5A and 5B (collectively “FIG. 5”) illustrate in two projection views a semiconductor wafer having semiconductor devices formed on it and configured for flip chip mounting, and an individual semiconductor die for flip chip mounting, respectively. In FIG. 5A, a semiconductor wafer 501 is shown with an array of semiconductor dies 502 formed in rows and columns on a surface. The semiconductor dies 502 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 503 and 504, which are perpendicular to one another, and which run in parallel groups across the semiconductor wafer 501, separate the rows and columns of the completed semiconductor dies 502, and provide areas for dicing the wafer to separate the semiconductor dies 502 from one another.

FIG. 5B illustrates a single semiconductor die 502, with bond pads 508, which are conductive pads that are electrically coupled to devices (not shown) formed in the semiconductor die 502. Conductive post connects 514 are shown extending away from a proximate end mounted on the bond pads 508 on the surface of semiconductor die 502 to a distal end, and solder bumps 516 are formed on the distal ends of the conductive post connects 514. The conductive post connects 514 can be formed by electroless plating or electroplating. In an example, the conductive post connects 514 are copper pillar bumps. Copper conductive post connects 514 can be formed by sputtering a seed layer over the surface of the semiconductor wafer 501, forming a photoresist layer over the seed layer, using photolithography to expose the bond pads 508 in openings in the layer of photoresist, plating the copper conductive post connects 514 on the bond pads, and plating a lead solder or a lead-free solder such as an tin, silver (SnAg) or tin, silver, copper (SnAgCu) or SAC solder to form solder bumps 516 on the copper conductive post connects 514. In alternative approach, solder bumps or particles may be dropped onto the distal ends of the copper pillar bumps and then reflowed in a thermal process to form bumps. Other conductive materials can be used for the conductive post connects in an electroplating or electroless plating operation, including gold, silver, nickel, palladium, or tin, for example. Not shown for clarity of illustration are under bump metallization (UBM) portions which can be formed over the bond pads to improve plating and adhesion between the conductive post connects 514 and the bond pads 508. After the plating operations, the photoresist is then stripped, and the excess seed layer is etched from the surface of the wafer. The semiconductor dies 502 are then separated by dicing, or are singulated, using the scribe lanes 503, 504 (see FIG. 5A).

FIG. 6 illustrates in a cross sectional view a multilayer package substrate 604 that can be used with the arrangements. In FIG. 6, the multilayer package substrate 604 has a device side surface 615 and a board side surface 605. Three trace layers 651, 653, 655 are formed spaced from one another by dielectric material, the trace layers are patterned for making horizontal connections, and three vertical conductor layers 652, 654, 656 form electrical connections between the three trace layers 651, 653, 655 and extend through the dielectric material 661 that is disposed over and between the trace layers. The dielectric material 661 can be a thermoplastic material such as ABS, or ASA, or can be a thermoset material, such as epoxy resin mold compound.

In one example the multilayer package substrate 604 has a substrate thickness labeled TS of 200 μm. The first trace layer, 651, near the device side surface 615 of the multilayer package substrate, has a trace layer thickness TL1 of 15 μm. The first vertical conductor layer, 652, has a thickness VC1 of 25 μm. The second trace layer, 653, sometimes coupled to the first trace layer by the first trace layer 651, has a thickness labeled TL2 of 60 μm. The second vertical connection layer, 654, has a thickness labeled VC2 of 65 μm. The third trace layer, 655, has a thickness labeled TL3 of 15 μm, and the third vertical connection layer, 656, has a thickness labeled VC3 of 25 μm. Additional layers, such as conductive lands on the device side surface 615, or terminals on the board side surface 605, may be formed by plating (not shown in FIG. 6). A continuous vertical connection between the device side surface 615 and the board side surface 605 (e.g., isolation walls 217 and reflection walls 209 (FIG. 2)) can be formed by patterning a stack of trace layers and the corresponding vertical connection layers to form a continuous conductive path extending through the dielectric material 661. Of importance, because the multilayer process described below with regard to FIG. 7 is used in these arrangements, isolation walls 217 and reflection walls 209 (FIG. 2) are continuous within each layer. That is, there are no gaps horizontally or vertically in the structures of isolation walls 217 and reflection walls 209 (FIG. 2) in this or any of the other arrangements discussed herein that include these structures. In the arrangements, an antenna 207-X (FIG. 2) can be formed by patterning the first trace layer 651, while a reflector 206 (FIG. 2) can be formed by patterning the third trace layer 655, for example. A lead 212 (FIG. 2) can be formed by patterning second trace layer 653 and vertical connectors 214 (FIG. 2) can be formed in first vertical connector layer 652. Isolation walls 217 and reflection walls 209-X (FIG. 2) can be formed by conductive traces in first trace layer 651, first vertical connector layer 652, second trace layer 653, and second vertical trace layer 654.

A semiconductor device mounting area positioned spaced from the antenna, as described above, can be formed by patterning the first trace layer 651. Note that in this description, the vertical conductor layers 652, 654, and 656 are not described as “vias” to distinguish the vertical connections of the arrangements from the vertical connections of PCBs or other substrates, which are filled via holes. The vertical connections of the arrangements are formed using additive manufacturing, while vias in PCBs are usually formed by removing material, for example via holes are drilled into the substrate. These via holes between conductor layers then must be plated and filled with a conductor, which requires additional plating steps after the drilling steps. These additional steps are precise manufacturing processes that add costs and require additional manufacturing tools and capabilities. In contrast the vertical connection layers used in the multilayer package substrates of the arrangements are formed in the same plating processes as forming the trace layers, simplifying manufacture, and reducing costs. In addition, the vertical connection layers in the arrangements can be arbitrary shapes, such as rails, columns, or posts, and the rails can be formed in continuous patterns to form electric shields, tubs, or tanks, and can be coupled to grounds or other potentials, isolating regions of the multilayer package substrate from one another. Noise reduction and the ability to create electrically isolated portions of the multilayer package substrate can be enhanced by use of the vertical connections to form tanks, shields, and tubs. Thermal performance of the microelectronic device packages of example arrangements can be improved by use of the vertical connection layers to form thermally conductive columns, sinks or rails that can be coupled to thermal paths on a system board to increase thermal dissipation from the semiconductor devices mounted on the multilayer package substrate.

FIGS. 7A-7B (collectively “FIG. 7) illustrate, in a series of cross-sectional views, selected steps for a method for forming a multilayer package substrate that is useful with the arrangements. In FIG. 7A, at step 701, a metal carrier 771 is readied for a plating process. The metal carrier 771 can be stainless steel, steel, aluminum or another metal that will support the multilayer package substrate layers during plating and molding steps, the multilayer package substrate is then removed, and the metal carrier is cleaned for additional manufacturing processes.

At step 703, a first trace layer 751 is formed by plating. In an example process, a seed layer is deposited over the surface of the metal carrier 771, by sputtering, chemical vapor deposition (CVD) or other deposition step. A photoresist layer is deposited over the seed layer, exposed, developed, and cured to form a pattern to be plated. Electroless or electroplating is performed using the exposed portions of the seed layer to start the plating, forming a pattern according to patterns in the photoresist layer.

At step 705, the plating process continues. A second photoresist layer is deposited, exposed, and developed to pattern the first vertical connection layer 752. By leaving the first photoresist layer in place, the second photoresist layer is used without an intervening strip and clean step, to simplify processing. The first trace layer 751 can be used as a seed layer for the second plating operation, to further simplify processing.

At step 707, a first molding operation is performed. The first trace layer 751 and the first vertical connection layer 752 are covered in a dielectric material. In an example a thermoplastic material is used, in a particular example ABS is used; in alternative examples ASA can be used, or a thermoset epoxy resin mold compound can be used, or resins, epoxies, or plastics can be used. In an example compressive molding operation, a mold compound can be heated to a liquid state, forced under pressure through runners into a mold to cover the first trace layer 751 and the first vertical connection layer 752, and subsequently cured to form solid mold compound layer 761.

At step 709, a grinding operation performed on the surface of the mold compound 761 exposes a surface of the vertical connection layer 752 and provides conductive surfaces for mounting devices, or for use in additional plating operations. If the multilayer package substrate is complete, the method ends at step 710, where a de-carrier operation removes the metal carrier 771 from the mold compound 761, leaving the first trace layer 751 and the first vertical connection layer 752 in a mold compound 761, providing a package substrate.

In examples where additional trace layers and additional vertical connection layers are needed, the method continues, leaving step 709 and transitioning to step 711 in FIG. 7B.

At step 711, a second trace layer 753 is formed by plating using the same processes as described above with respect to step 705. A seed layer for the plating operation is deposited and a photoresist layer is deposited and patterned, and the plating operation forms the second trace layer 753 over the mold compound 761, with portions of the second trace layer 753 electrically connected to the first vertical connection layer 752.

At step 713, a second vertical connection layer 754 is formed using an additional plating step on the second trace layer 753. The second vertical connection layer 754 can be plated using the second trace layer 753 as a seed layer, and without the need for removing the preceding photoresist layer, simplifying the process.

At step 715, a second molding operation is performed to cover the second trace layer 753 and the second vertical connection layer 754 in a layer of mold compound 763. The multilayer package substrate at this stage has a first trace layer 751, a first vertical connection layer 752, a second trace layer 753, and a second vertical connection layer 754, portions of the layers are electrically connected together to form vertical paths through the mold compound layers 761 and 763.

At step 717, the mold compound layer 763 is mechanically ground in a grinding process or chemically etched to expose a surface of the second vertical connection layer 754. At step 719 the example method ends by removing the metal carrier 771, leaving a multilayer package substrate including the connection layers 751, 752, 753 and 754 in dielectric layers 761, 763. The steps of FIGS. 7A-7B can be repeated to form multilayer package substrates for use with the arrangements having more layers, by performing plating of a trace layer, plating of a vertical connection layer, molding, and grinding, repeatedly.

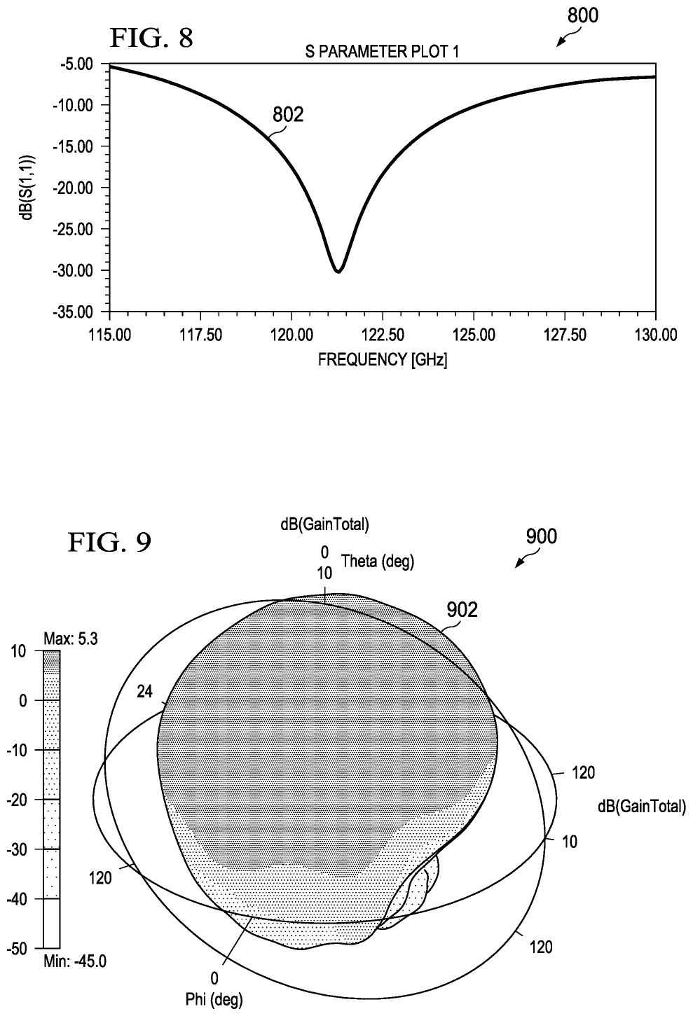

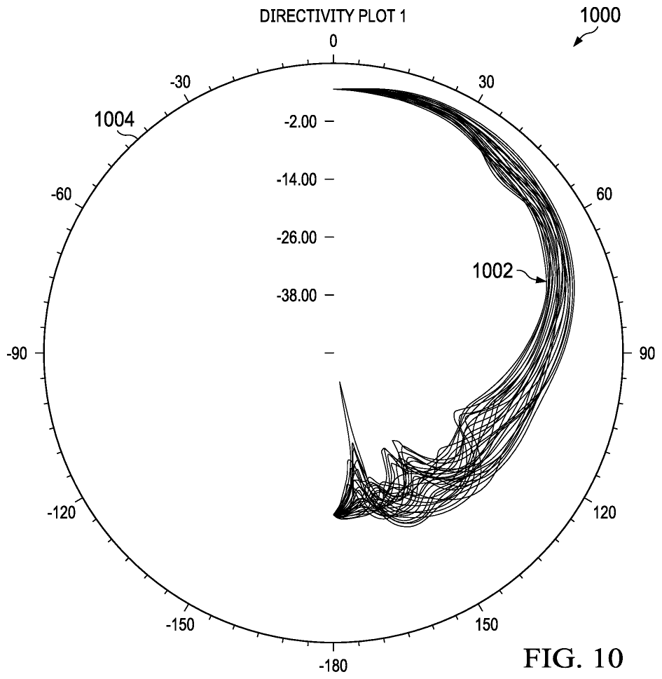

FIG. 8 illustrates, in a graph 800, a curve 802 illustrating the S parameters for the example antenna of FIG. 3, showing simulation results. As shown in FIG. 8, the S curve 802 has a trough of approximately −30 db at about 121.5 GHz. This indicates that, at 121.5 GHz, most of the energy applied to antenna 207-X is transmitted rather than reflected back to the S measurement device. Thus, at 121.5 GHz, antenna 207-X efficiently transmits the signal. FIG. 9 is a three-dimensional radiation lobe chart 900 of an example antenna 207-X. The distance of surface 902 from the central axis shows the relative intensity of the transmitted signal. Of note is strongest signal is in the θ=0 direction, showing good directionality in the θ=0 direction. FIG. 10 is a directivity plot 1000 of an example antenna 207-X also showing good directivity. Each of the lines 1002 is a measurement of signal intensity at a selected frequency. The farther from the center of circle 1004, the stronger the signal.

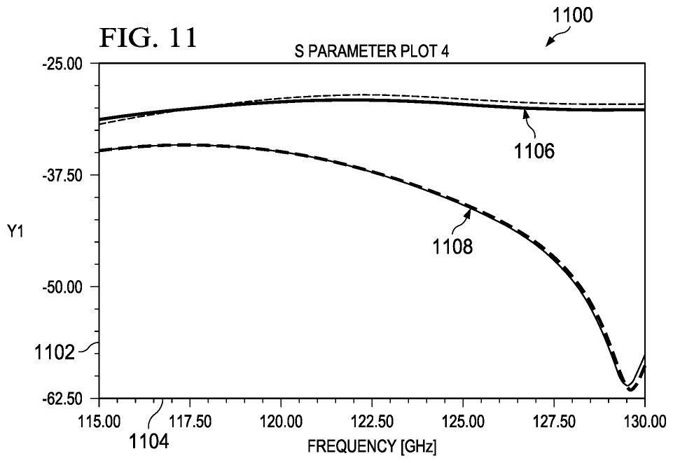

FIG. 11 is a graph 1100 of crosstalk in an example antenna array 208. The vertical axis 1102 is the strength of the crosstalk signal in decibels. The horizontal axis 1104 is the frequency of the applied signal. Lines 1106 show that cross talk with adjacent antennas (e.g., antenna 207-1 and antenna 207-2 (FIG. 2)) is below −30 db for all measured frequencies. That is, the signal is at least 30 db below the applied signal (i.e., 0 db). When making small monolithic phased arrays, it is a significant challenge to avoid crosstalk between antennas, which can significantly decrease the desired directionality of the beam formed using the phased array. Line 1106 shows that crosstalk is well controlled in example antenna array 208 (FIG. 2). Lines 1108 show that crosstalk between diagonally oriented antennas (e.g., antenna 207-1 and antenna 207-4) is lower than the crosstalk of lines 1106. This data shows that crosstalk in example antenna array 208 is well controlled.

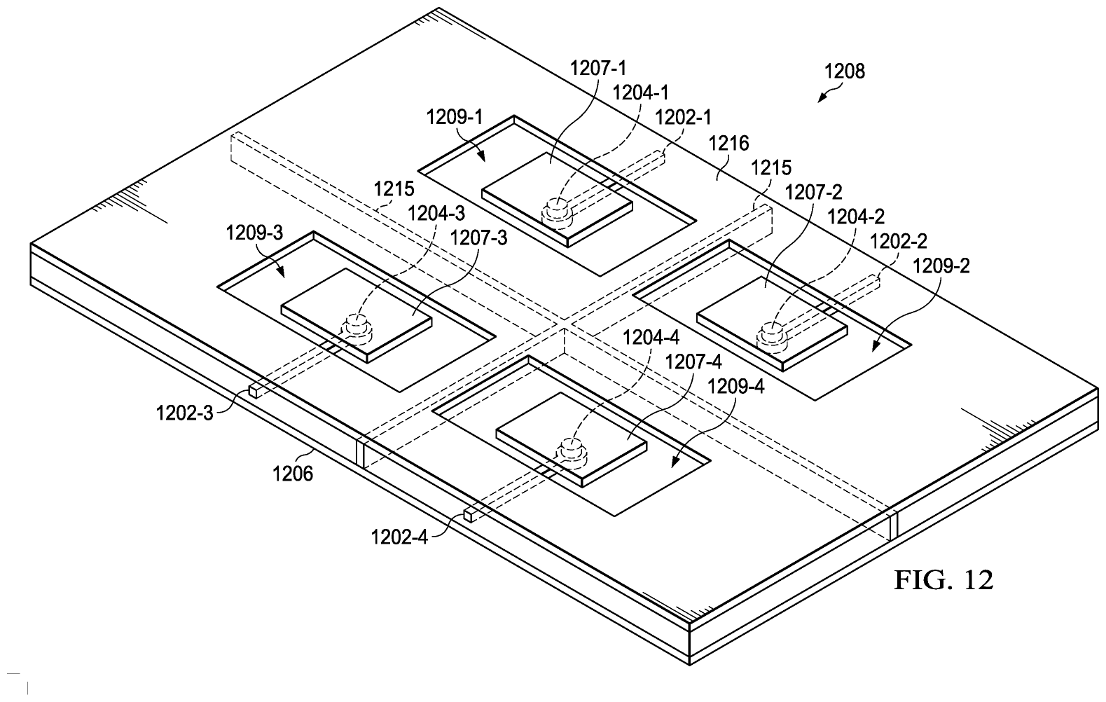

FIG. 12 is a perspective view of another example antenna array 1208. Antennas 1207-1 through 1207-4 are examples of antennas 207-1 through 207-4 (FIG. 3), respectively. Openings 1209-1 through 1209-4 are examples of openings 308-1 through 308-4 (FIG. 3), respectively. Reflector 1206 is an example of reflector 206 (FIG. 3). Top ground layer 1216 is an example of top ground layer 306 (FIG. 3). Leads 1202-1 through 1202-4 are examples of leads 302-1 through 302-4 (FIG. 3), respectively. Conductive post connects 1204-1 through 1204-4 are examples of conductive post connects 304-1 through 304-4 (FIG. 3), respectively. Isolation walls 1215 are examples of isolation walls 217 (FIG. 3). Antenna array 1208 does not include reflection walls like reflection walls 308-1 through 308-4 (FIG. 3).

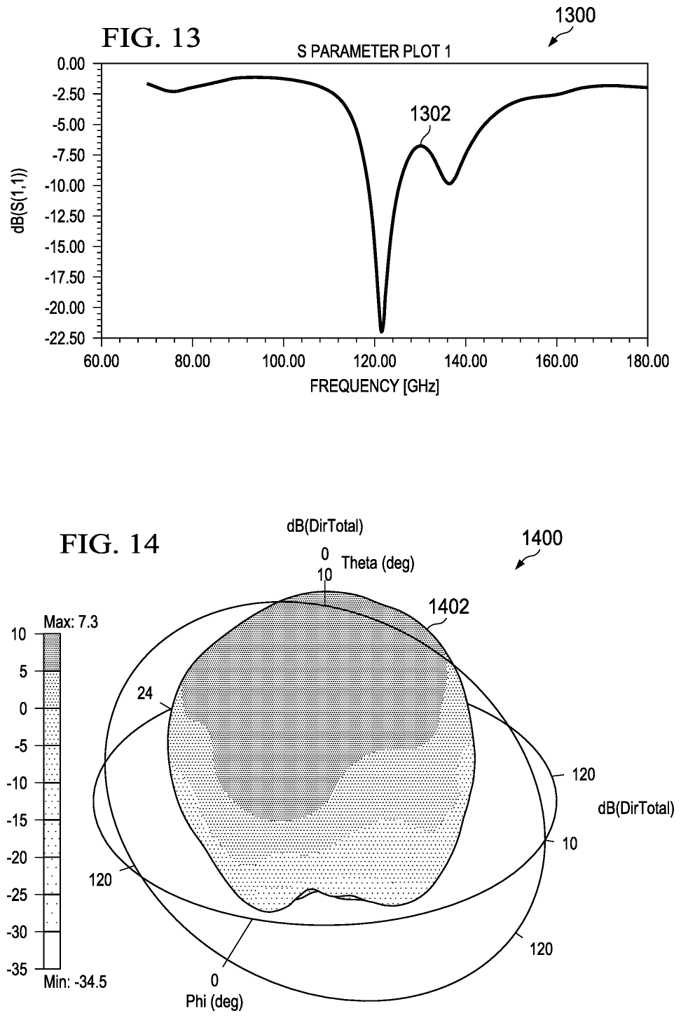

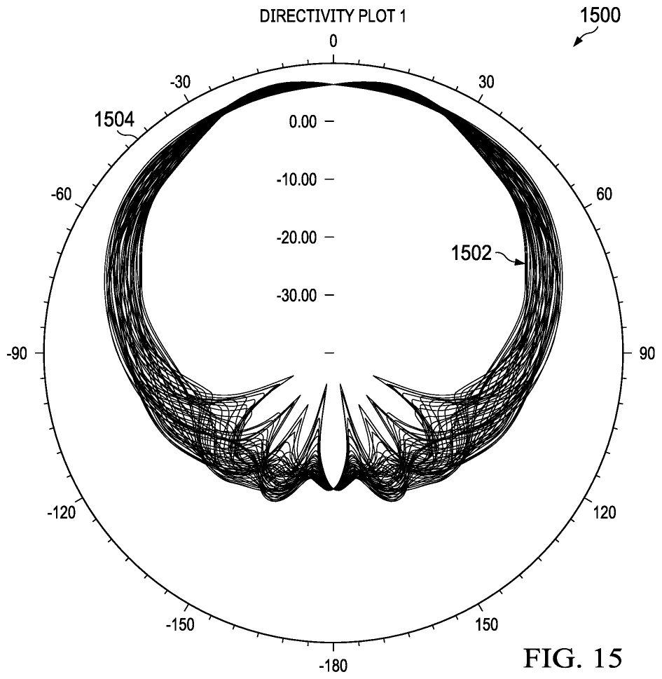

FIG. 13 illustrates, in a graph 1300, a curve 1302 illustrating the S parameters for the example antenna of FIG. 12, showing simulation results. As shown in FIG. 13, the S curve 1302 has a trough of approximately −30 db at about 121 GHz. This indicates that, at 121 GHz, most of the energy applied to antenna 1207-X is transmitted rather than reflected back to the S measurement device. Thus, at 121 GHz, antenna 1207-X efficiently transmits the signal. FIG. 14 is a three-dimensional radiation lobe chart 1400 of an example antenna 1207-X. The distance of surface 1402 from the central axis shows the relative intensity of the transmitted signal. Of note is strongest signal is in the θ=0 direction, showing good directionality in the θ=0 direction. FIG. 15 is a directivity plot 1500 of an example antenna 1207-X also showing good directivity. Each of the lines 1502 is a measurement of signal intensity at a selected frequency. The farther from the center of circle 1504, the stronger the signal.

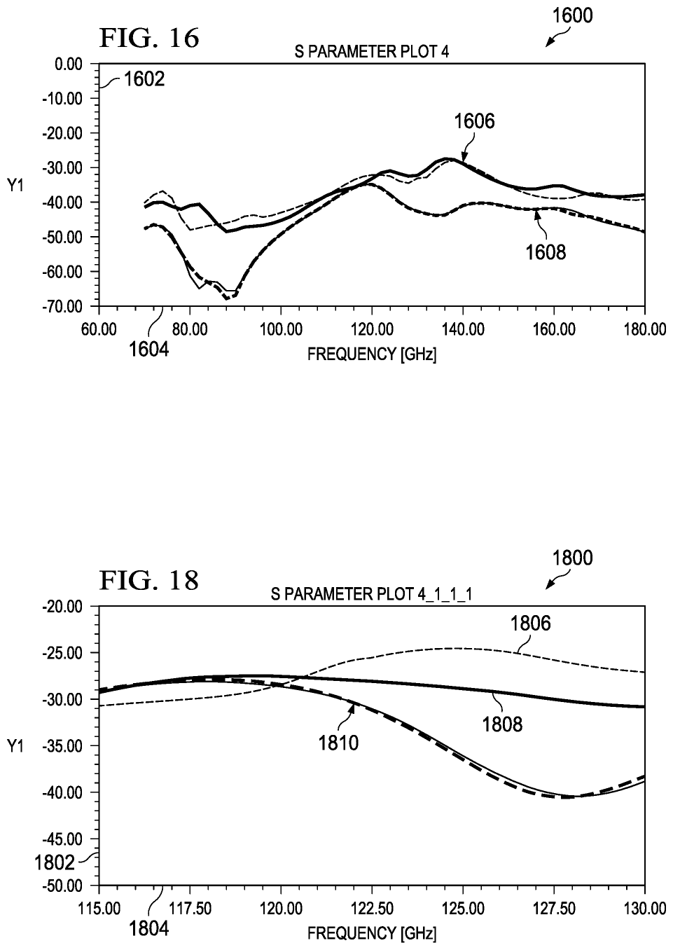

FIG. 16 is a graph 1600 of crosstalk in an example antenna array 1208. The vertical axis 1602 is the strength of the crosstalk signal in decibels. The horizontal axis 1604 is the frequency of the applied signal. Lines 1606 show that cross talk with adjacent antennas (e.g., antenna 1207-1 and antenna 1207-2) is below −30 db for all measured frequencies. That is, the signal is at least 30 db below the applied signal (i.e., 0 db). However, lines 1606 show that the crosstalk levels of the arrangement of FIG. 12 is good, it is not as good as the crosstalk levels of the arrangement of FIG. 3. Lines 1608 show that crosstalk between diagonally oriented antennas (e.g., antenna 1207-1 and antenna 1207-4) is lower than the crosstalk of lines 1606. This data shows that crosstalk in the arrangement of FIG. 12 is not as good as the example antenna array 208 (FIG. 3) but is still well controlled.

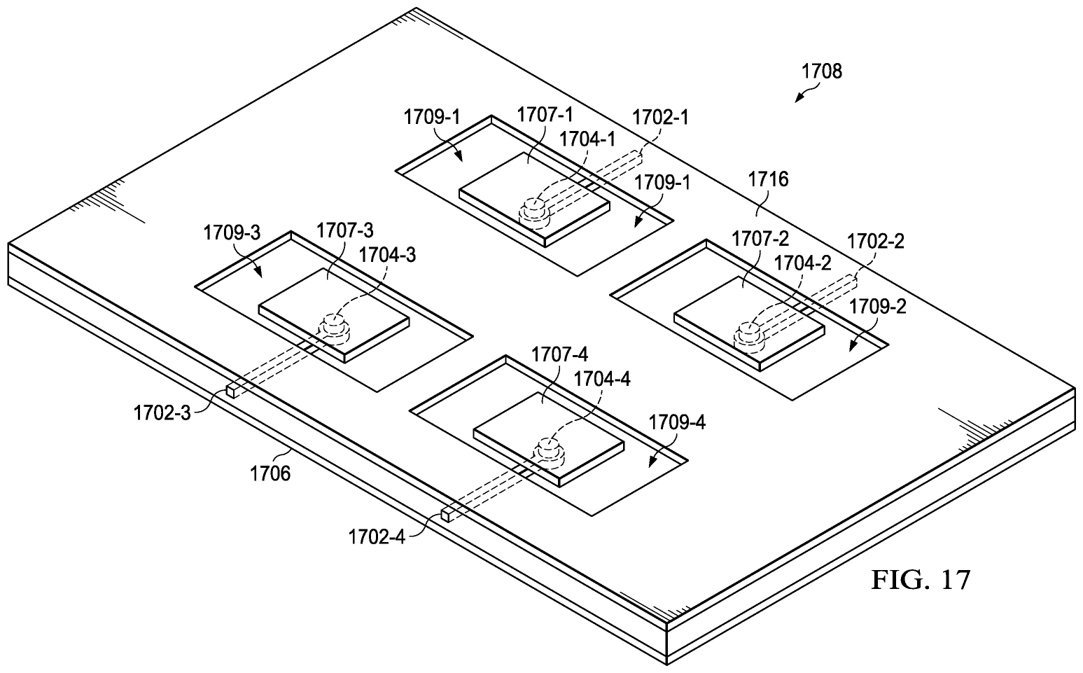

FIG. 17 is a perspective view of another example antenna array 1708. Antennas 1707-1 through 1707-4 are examples of antennas 207-1 through 207-4 (FIG. 3), respectively. Openings 1709-1 through 1709-4 are examples of openings 308-1 through 308-4 (FIG. 3), respectively. Reflector 1706 is an example of reflector 206 (FIG. 3). Top ground layer 1716 is an example of top ground layer 306 (FIG. 3). Leads 1702-1 through 1702-4 are examples of leads 212 (FIG. 3). Conductive post connects 1704-1 through 1704-4 are examples of conductive post connects 213 (FIG. 3). The arrangement of FIG. 17 does not include isolation walls like isolation walls 217 (FIG. 3). Antenna array 1708 also does not include reflection walls like reflection walls 209-1 through 209-4 (FIG. 3).

FIG. 18 is a graph 1800 of crosstalk in an example antenna array 1708. The vertical axis 1802 is the strength of the crosstalk signal in decibels. The horizontal axis 1804 is the frequency of the applied signal. Lines 1806 and 1808 show that cross talk with adjacent antennas (e.g., antenna 1707-1 and antenna 1707-2) is greater than −30 db for most measured frequencies. That is, the signal can be more than 30 db below the applied signal (i.e., 0 db). Lines 1810 show that crosstalk in non-adjacent antennas is generally lower that lines 1806 and 1808, but still can be greater than −30 db.

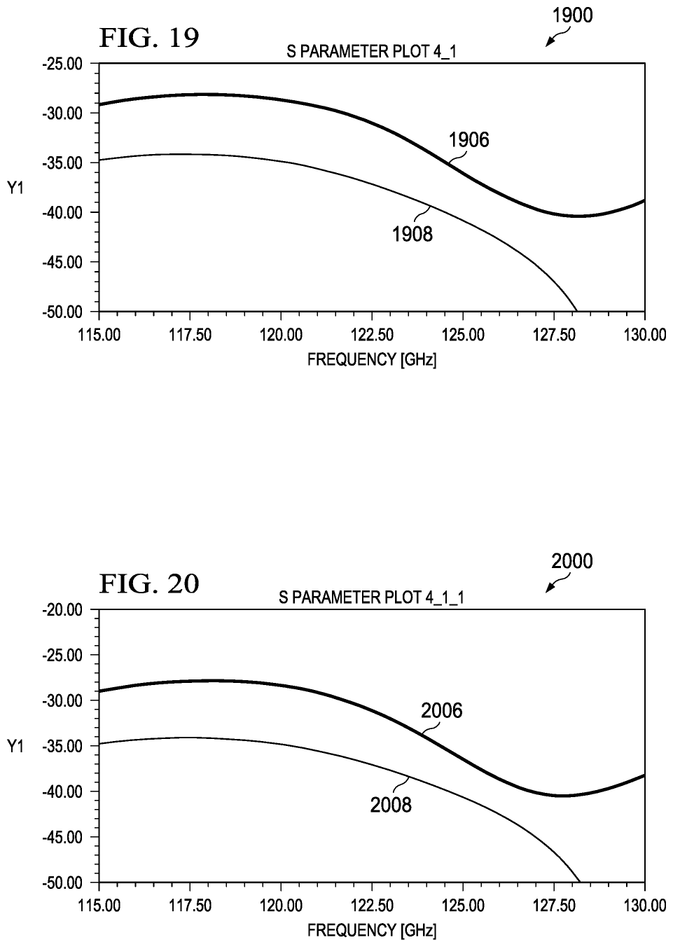

FIG. 19 is a graph 1900 comparing the crosstalk in non-adjacent antennas in the arrangements of FIG. 3 and FIG. 17. Line 1906 is the crosstalk for non-adjacent antennas in the arrangement of FIG. 17. Line 1908 is the crosstalk for non-adjacent antennas in the arrangement of FIG. 3. This shows that the use of isolation walls 217 (FIG. 3) and vertical reflection walls 209-1 through 209-4 improves the level of crosstalk by about 10 db.

FIG. 20 is a graph 2000 comparing the crosstalk in non-adjacent antennas in the arrangements of FIG. 12 and FIG. 17. Line 2006 is the crosstalk for non-adjacent antennas in the arrangement of FIG. 17. Line 2008 is the crosstalk for non-adjacent antennas in the arrangement of FIG. 12. This shows that the use of isolation walls 1215 (FIG. 12) improves the level of crosstalk by about 7 db.

The use of the arrangements provides a microelectronic device package with an integrated antennas suitable for use as a phased array and a semiconductor die. Existing materials and assembly tools are used to form the arrangements, and the arrangements are low in cost when compared to solutions using additional circuit boards or modules to carry the antennas. The arrangements are formed using existing methods, materials and tooling for making the devices and are cost effective.

Modifications are possible in the described examples, and other examples are possible, within the scope of the claims.

What is claimed is:

1. An apparatus, comprising:
a first antenna and a second antenna formed in a first layer on a first surface of a multilayer package substrate, the multilayer package substrate comprising layers including patterned conductive portions and dielectric portions, the multilayer package substrate having a second surface opposite the first surface;
an isolation wall formed in the multilayer package substrate formed in at least a second and a third layer in the multilayer package substrate; and
a semiconductor die mounted to the first surface of the multilayer package substrate spaced from and coupled to the first antenna and the second antenna.

2. The apparatus of claim 1, wherein the multilayer package substrate and the semiconductor die are included in a microelectronic device package.

3. The apparatus of claim 2, wherein the microelectronic device package includes a mold compound protecting the semiconductor die and the multilayer package substrate.

4. The apparatus of claim 1, further comprising a reflector formed in a fourth layer of the multilayer package substrate.

5. The apparatus of claim 4, further comprising a top ground layer in the first layer of the multilayer package substrate, the top ground layer having a first opening in which the first antenna is formed and a second opening in which the second antenna is formed.

6. The apparatus of claim 5, wherein the isolation wall extends from the top ground layer to the reflector.

7. The apparatus of claim 5, further comprising:
a first lead coupled to the first antenna and extending from the first antenna;
a second lead coupled to the second antenna and extending from the second antenna;
first lateral reflection walls extending from the top ground layer to the reflector, the first lateral reflection walls surrounding the first antenna except where the first lead extends from the first antenna; and
second lateral reflection walls extending from the top ground layer to the reflector, the second lateral reflection walls surrounding the second antenna except where the second lead extends from the second antenna.

8. The apparatus of claim 7, wherein the first lead is coupled to the first antenna via a first post and the second lead is coupled to the second antenna via a second post.

9. An apparatus, comprising:
a first antenna and a second antenna formed in a first layer on a first surface of a multilayer package substrate, the multilayer package substrate comprising layers including patterned conductive portions and dielectric portions, the multilayer package substrate having a second surface opposite the first surface;
a semiconductor die mounted to the first surface of the multilayer package substrate spaced from and coupled to the first antenna and the second antenna;
a reflector formed in a fourth layer of the multilayer package substrate;
a top ground layer in the first layer of the multilayer package substrate, the top ground layer having a first opening in which the first antenna is formed and a second opening in which the second antenna is formed;
an isolation wall formed in the multilayer package substrate formed in at least a second and a third layer in the multilayer package substrate, wherein the isolation wall extends from the top ground layer to the reflector;
a first lead coupled to the first antenna and extending from the first antenna;
a second lead coupled to the second antenna and extending from the second antenna;
first lateral reflection walls extending from the top ground layer to the reflector, the first lateral reflection walls surrounding the first antenna except where the first lead extends from the first antenna, wherein a sum of a first distance from the first lateral reflection walls to the first antenna plus a second distance between the top ground layer and the reflector is equal to a wavelength of a frequency which the first antenna is configured to transmit or receive; and
second lateral reflection walls extending from the top ground layer to the reflector, the second lateral reflection walls surrounding the second antenna except where the second lead extends from the second antenna.

10. The apparatus of claim 9, wherein the first lead is coupled to the first antenna via a first post and the second lead is coupled to the second antenna via a second post.

11. The apparatus of claim 9, wherein the multilayer package substrate and the semiconductor die are included in a microelectronic device package.

12. The apparatus of claim 11, wherein the microelectronic device package includes a mold compound protecting the semiconductor die and the multilayer package substrate.

13. An apparatus, comprising:
a first antenna and a second antenna formed in a first layer on a first surface of a multilayer package substrate, the multilayer package substrate comprising layers including patterned conductive portions and dielectric portions, the multilayer package substrate having a second surface opposite the first surface;
an isolation wall formed in the multilayer package substrate formed in at least a second and a third layer in the multilayer package substrate; and
a semiconductor die mounted to the second surface of the multilayer package substrate and coupled to the first antenna and the second antenna.

14. The apparatus of claim 13, wherein the multilayer package substrate and the semiconductor die are included in a microelectronic device package.

15. The apparatus of claim 14, wherein the microelectronic device package includes a mold compound protecting the semiconductor die and the multilayer package substrate.

16. The apparatus of claim 13, further comprising a reflector formed in a fourth layer of the multilayer package substrate.

17. The apparatus of claim 16, further comprising a top ground layer in the first layer of the multilayer package substrate, the top ground layer having a first opening in which the first antenna is formed and a second opening in which the second antenna is formed.

18. The apparatus of claim 17, wherein the isolation wall extends from the top ground layer to the reflector.

19. The apparatus of claim 17, further comprising:
a first lead coupled to the first antenna and extending from the first antenna;
a second lead coupled to the second antenna and extending from the second antenna;
first lateral reflection walls extending from the top ground layer to the reflector, the first lateral reflection walls surrounding the first antenna except where the first lead extends from the first antenna; and
second lateral reflection walls extending from the top ground layer to the reflector, the second lateral reflection walls surrounding the second antenna except where the second lead extends from the second antenna.

20. The apparatus of claim 19, wherein the first lead is coupled to the first antenna via a first post and the second lead is coupled to the second antenna via a second post.
